(19) United States
(12) Patent Application Publication
(10) Pub. No.: US 2013/0040435 A1
(43) Pub. Date: Feb. 14, 2013

(54) METHOD FOR MANUFACTURING TRANSISTOR AND SEMICONDUCTOR DEVICE

(71) Applicants: Haizhou Yin, Poughkeepsie, NY (US); Zhijiong Luo, Poughkeepsie, NY (US); Huilong Zhu, Poughkeepsie, NY (US)

(72) Inventors: Haizhou Yin, Poughkeepsie, NY (US); Zhijiong Luo, Poughkeepsie, NY (US); Huilong Zhu, Poughkeepsie, NY (US)

(21) Appl. No.: 13/377,527

(22) PCT Filed: Aug. 9, 2011
(86) PCT No.: PCT/CN2011/001317

§ 371 Date: Dec. 9, 2011

(51) Int. Cl. H01L 21/336

(52) U.S. Cl. 438/299; 257/E21.444

(57) ABSTRACT

A method for manufacturing a transistor and a semiconductor device is provided. The method for manufacturing a transistor may comprise: defining an active area on a semiconductor substrate, and forming on the active area a gate stack or a dummy gate stack, a source/drain extension region, a spacer and a source/drain region, wherein the source/drain extension region is embedded in the active area and self-aligned on both sides of the gate stack or dummy gate stack, the spacer surrounds the gate stack or dummy gate stack, and the source/drain region is embedded in the active area and self-aligned outside the spacer; removing at least a portion of the spacer to expose a portion of the active area; and forming an interlayer dielectric layer which covers the gate stack or dummy gate stack, the spacer and the exposed active area, wherein the dielectric constant of the material of the interlayer dielectric layer is smaller than that of the removed material of the spacer. It is beneficial for reducing the capacitance between the gate region and the source/drain region as well as between the gate region and the contact plug.

### FIELD OF THE INVENTION

The present invention generally relates to the semiconductor technology, and more particularly to a method for manufacturing a transistor and a semiconductor device.

### BACKGROUND OF THE INVENTION

As transistors, like the metal oxide field effect transistor (MOSFET) are gradually decreasing in size, the distance between the gate region and the source/drain region as well as the distance between the gate region and the contact plug for the transistor is also decreasing. One can find from the formula for calculating capacitance, C=kA/d, that the capacitance is inversely proportional to the distance d, and directly proportional to the value of the dielectric constant k. This means that when the distance between the gate region and the source/drain region decreases gradually and even approaches zero, the capacitance between the gate region and the source/drain region will increase rapidly. Similarly, the capacitance between the gate region and the contact plug will also increase rapidly. This may result in significant increase of the total capacitance of the transistor, which will greatly influence the speed and performance of the transistor.

It is generally considered in the art that a material with a k value larger than 25 is a high k material, a material with a k value smaller than 8.0 and larger than 3.85 is a medium k material, and a material with a k value smaller than 3.85 is a low k material. In the prior art, in order to reduce the capacitance between the gate region and the source/drain region as well as between the gate region and the contact plug, the skilled in the art have imagined to use a nitride (e.g. silicon nitride) with a moderate k value as a spacer layer, and meanwhile for preventing the external oxygen entering the gate during high temperature annealing. However, since silicon nitride belongs to a medium k material due to the k value of about 7, with further decrease in the size of transistor, the capacitance between the gate region and the source/drain region as well as between the gate region and the contact plug will still increase significantly. As a result, the improvement in the speed and performance of the transistor is strongly limited.

To this end, there is an urgent need in the art for improvement in the transistor technology.

### SUMMARY OF THE INVENTION

In view of this, the present invention provides a method for manufacturing a transistor and a semiconductor device, which can solve or at least alleviate at least partially the drawbacks in the prior art.

According to the first aspect of the present invention, it is provided a method for manufacturing a transistor, comprising the steps of:

defining an active area on a semiconductor substrate, and forming on the active area a gate stack or a dummy gate stack, a source/drain extension region, a spacer and a source/drain region, wherein the source/drain extension region is embedded in the active area and self-aligned on both sides of the gate stack or dummy gate stack, the spacer surrounds the gate stack or dummy gate stack, and the source/drain region is embedded in the active area and self-aligned outside the spacer;

removing at least a portion of the spacer to expose a portion of the active area; and

forming an interlayer dielectric layer which covers the gate stack or dummy gate stack, the spacer and the exposed active area, wherein the dielectric constant of the material of the interlayer dielectric layer is smaller than that of the removed material of the spacer.

In an embodiment of the present invention, after forming the interlayer dielectric layer, the method further comprises:

forming contact holes in the interlayer dielectric layer to expose a portion of the active area; and

forming a contact layer on the exposed active area.

In another embodiment of the present invention, the step of forming the contact layer comprises:

forming a metal layer to cover sidewalls of the contact hole and the exposed active area;

annealing so that the material of the metal layer reacts with the exposed active area to form a metal semiconductor material; and

removing the unreacted material of the metal layer.

In yet another embodiment of the present invention, the spacer comprises a spacer base layer and a primary spacer formed on the spacer base layer, and when the dielectric constant of the material of the primary spacer is larger than that of the material of the spacer base layer, the step of removing at least a portion of the spacer comprises: removing the primary spacer.

In a further embodiment of the present invention, when the material of the semiconductor substrate is Si, the material of the spacer base layer is silicon oxide, and the material of the primary spacer is silicon nitride, the dielectric constant of the material of the interlayer dielectric layer is smaller than that of silicon nitride.

In another embodiment of the present invention, the dielectric constant of the material of the interlayer dielectric layer is smaller than that of silicon oxide.

In yet another embodiment of the present invention, when the material of the semiconductor substrate is Si, the material of the interlayer dielectric layer is carbon (C)-doped silica glass.

In a further embodiment of the present invention, after forming the interlayer dielectric layer, the method further comprises:

planarizing the interlayer dielectric layer to expose the dummy gate stack;

removing the dummy gate stack to form a cavity; and

forming the gate stack in the cavity.

According to the second aspect of the present invention, it is provided a method for manufacturing a semiconductor device, which may comprise the steps of the method for manufacturing a transistor as described above.

In accordance with the method for manufacturing a transistor of the present invention, after the spacer is formed to surround the gate stack or dummy gate stack, at least a portion of the spacer is removed to expose a portion of the active area, and then the gate stack or dummy gate stack, the spacer and the exposed active area are covered by the interlayer dielectric layer with a dielectric constant smaller than that of the material of the removed spacer. Namely, the original spacer material is replaced by the interlayer dielectric layer with a smaller dielectric constant, which forms the isolation between the gate region and the source/drain region as well as between the gate region and the contact plug. In fact, this reduces the dielectric constant between the gate region and the source/drain region as well as between the gate region and the contact plug, and thus makes it possible to reduce the capacitance between the gate region and the source/drain region as well as between the gate region and the contact plug, and helps to improve the performance of the transistor.

By forming the contact layer after formation of the interlayer dielectric layer, it is advantageous in that the damage to the formed contact layer during the process for removing at least a portion of the spacer is reduced.

### BRIEF DESCRIPTION OF THE DRAWINGS

The above and other features of the present invention will be more apparent from the embodiments described in details hereinafter and shown in the accompanying drawings, in which:

FIG. 1 schematically illustrates the flow chart of a method for manufacturing a transistor according to an embodiment of the present invention; and

FIGS. 2-6 schematically illustrate structural sectional views of intermediate structures during manufacturing a transistor according to an embodiment of the present invention.

### DESCRIPTION OF EMBODIMENTS

Firstly, it should be noted that terms regarding position and orientation mentioned in the present invention, such as “above”, “below”, etc., refer to the directions as viewed from the front of the paper in which the drawings are located. Therefore, the terms “above”, “below”, etc. regarding position and orientation in the present invention only indicate the relative positional relationship in the case as shown in the drawings. They are presented only for purpose of illustration, but not intend to restrict the scope of the present invention.

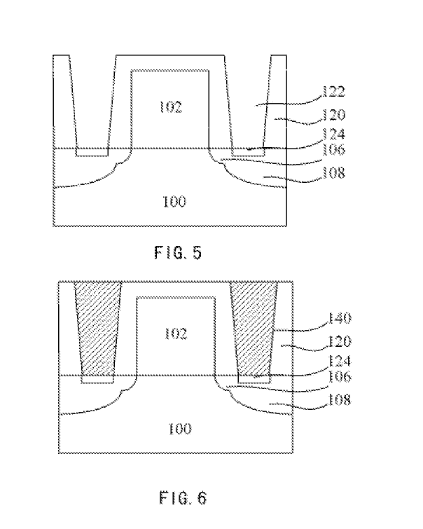

Hereinafter, the solutions provided by the present invention will be described in details with reference to the accompanying drawings. A Si substrate is shown in FIGS. 2-6 by way of example. However, in addition to Si substrate, any suitable semiconductor substrate, like SiGe substrate, III-V group elements compound substrate, silicon carbide substrate, SOI (silicon on insulator) substrate, etc., can also be used. Therefore, the present invention is not limited to the case of Si substrate as shown.

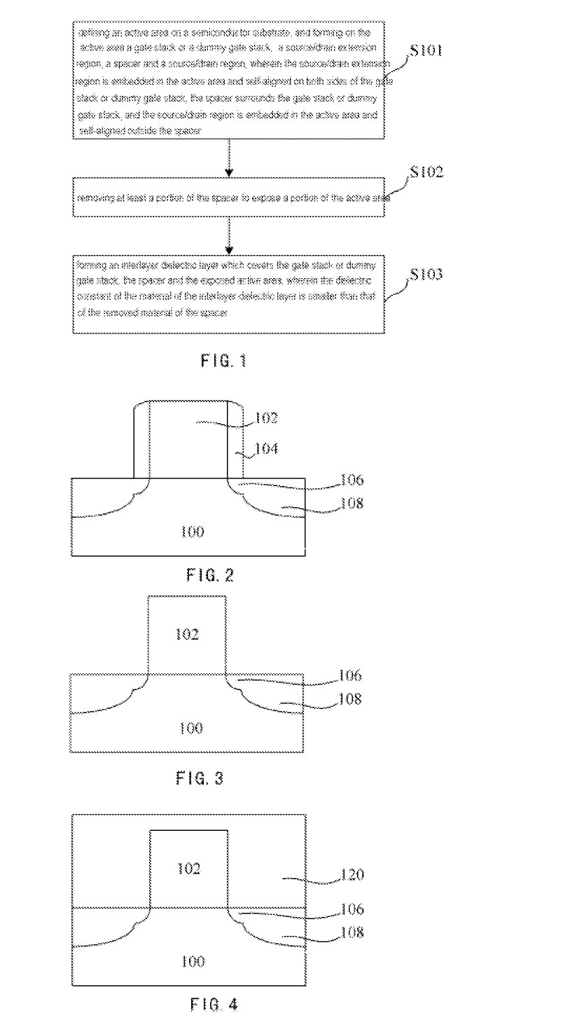

As shown in FIGS. 1-2, in step S101, an active area is defined on a semiconductor substrate 100, and on the active area a gate stack or dummy gate stack 102, a source/drain extension region 106, a spacer 104, and a source/drain region 108 are formed. The source/drain extension region 106 is embedded in the active area and self-aligned on both sides of the gate stack or dummy gate stack 102. The spacer 104 surrounds the gate stack or dummy gate stack 102. The source/drain region 108 is embedded in the active area and self-aligned outside the spacer 104.

The gate stack or dummy gate stack 102 may comprise a gate dielectric layer formed on the active area and a gate electrode formed on the gate dielectric layer. In this embodiment, the gate dielectric layer may be formed by silicon oxide, silicon nitride, or the combination thereof. In other embodiments, it may also be one of the high K dielectric (which can be formed by chemical vapor deposit process) selected from the group consisting of, for example, HfO₂, HfSiO, HfSiON, HfTaO, HfTiO, HfZrO, Al₂O₃, La₂O₃, ZrO₂, and LaAlO, or any combination thereof. Its thickness may range from 2 nm to 10 nm. The gate electrode may be doped or un-doped polycrystalline silicon, doped or un-doped polycrystalline SiGe, amorphous Si, and/or metal (e.g. one or any combination of Ti, Co, Ni, Al, and W). The gate electrode in the dummy gate stack may also be doped or un-doped silicon oxide, silicon nitride, SiON and/or silicon carbide, and its thickness may range from 10 nm-80 nm. Furthermore, it is also possible that the gate dielectric layer is not included in the dummy gate stack.

Then, with the gate stack or dummy gate stack 102 as a mask, the source/drain extension region 106 is formed in a self aligning manner; and a spacer 104 is formed to surround the gate stack or dummy gate stack 102. The material of the spacer 104 may be either an oxygen-free dielectric material (e.g. silicon nitride or silicon carbide), or a stack structure (e.g. an ON structure, i.e., the portion adjoining the gate stack or dummy gate stack 102 is a silicon oxide layer on which a silicon nitride layer is further arranged, and the silicon oxide layer and the silicon nitride layer together constitute the spacer 104; similarly, other oxygen-free dielectric materials can also be arranged on the silicon oxide layer so as to constitute the spacer 104 together). The oxygen-free dielectric material can prevent the external oxygen or oxygen ion from reacting with the gate formed by the metal material due to the high temperature annealing process used in the process for manufacturing the transistor, which otherwise may influence the performance of the transistor and even that of the integrated circuit. Since the dielectric constant of silicon nitride is about 7, which is lower that the dielectric constant of 9.66 for silicon carbide, it is preferred to use silicon nitride as the material for the spacer.

Then, a source/drain region is formed on the semiconductor substrate. In particular, ions of a certain dose can be implanted to form a doped region, and then it is annealed so that the expected distribution and activity of the implanted ions can be realized. For example, as for NMOS and PMOS transistors, it is required to implant different types of dopants. The process parameters used during ion implantation, like implantation ion, implantation dose, implantation time, etc., would not be difficult to achieve for the skilled in the art based on their knowledge. The annealing process can be carried out in an oxygen-free atmosphere, like in N₂, Ar, etc. The annealing temperature and time can be easily determined according to different requirements for annealing by the skilled in the art based on their knowledge. Optionally, after the annealing process, the steps of implantation and annealing are performed repeatedly in order to achieve better ion distribution and activity.

Alternatively, the source/drain region can also be formed in the following manner, i.e., by taking the gate stack or dummy gate stack and the spacer as a mask, a trench for forming the source/drain region is formed in the semiconductor substrate by etching in a self aligning manner, then a Si-containing semiconductor material is formed in the trench by epitaxial growth (or by additional in-situ doping). For example, as for a PMOS transistor, Si, SiGe can be formed; and as for a NMOS transistor, SiC or the like can be formed.

Subsequently, as shown in FIGS. 1 and 3, in step S102, at least a portion of the spacer 104 is removed to expose a portion of the active area.

Preferably, the spacer 104 is completely removed, so that after subsequent formation of the interlayer dielectric layer, only the material of the interlayer dielectric layer, instead of any material of the spacer with a relatively high k value, is kept between the gate stacks or dummy gate stacks.

In the event that the material of the spacer with a relatively high k value accomplishes its expected task (i.e., preventing the oxygen or oxygen ion from migrating into the metal gate and reacting with it during high temperature annealing, and acting as the mask for forming the source/drain region in a self aligning manner), due to the relatively large dielectric constant of the material for the spacer, as described above, the silicon nitride has a dielectric constant of about 7, at least a portion of the spacer is removed, and then the material of the original spacer is replaced by the material of the interlayer dielectric layer with smaller dielectric constant, so as to form the isolation between the gate region and the source/drain region as well as between the gate region and the contact plug. This in fact reduces the dielectric constant between the gate region and the source/drain region as well as between the gate region and the contact plug, and thus makes it possible to reduce the capacitance between the gate region and the source/drain region as well as between the gate region and the contact plug, and helps to improve the performance of the transistor.

Then, with reference to FIGS. 1 and 4, in step S103, an interlayer dielectric layer 120 is formed to cover the gate stack or dummy gate stack 102, the spacer 104 and the exposed active area. The dielectric constant of the material of the interlayer dielectric layer 120 is smaller than that of the material of the removed the spacer 104.

In this embodiment, preferably, the material used in the interlayer dielectric layer 120 is a medium k or low k material. Preferably, when the material of the semiconductor substrate 100 is Si, the material of the spacer base layer is silicon oxide, and the material of the primary spacer is silicon nitride, the dielectric constant of the material of the interlayer dielectric layer 120 may be smaller than that of silicon nitride. In other embodiments, when the spacer 104 comprises a spacer base layer and a primary spacer formed thereon, and the dielectric constant of the material of the primary spacer is larger than that of the material of the spacer base layer, the step of removing at least a portion of the spacer 104 may comprise: removing the primary spacer. In this case, the material of the semiconductor substrate 100 is Si, the material of the spacer base layer is silicon oxide, and the material of the primary spacer is silicon nitride, the dielectric constant of the material of the interlayer dielectric layer 120 is smaller than that of silicon nitride. The dielectric constant of the material of the interlayer dielectric layer 120 may even be smaller than that of silicon oxide. Preferably, when the material of the semiconductor substrate 100 is Si, the material of the interlayer dielectric layer 120 may be C-doped silica glass, because C-doped silicon oxide has a smaller k value of about 2.7 and belongs to the low k material.

Furthermore, preferably, after the material of the interlayer dielectric layer 120 is deposited, for example by utilizing a chemical mechanical polishing (CMP) process, the deposited material of the interlayer dielectric layer 120 is polished on the upper surface to ensure the flatness of the interlayer dielectric layer 120. This can also be done by other polishing processes well known in the art.

Specifically, when a dummy gate stack is formed before formation of the interlayer dielectric layer 120, the process may further comprise, after forming the interlayer dielectric layer 120: planarizing the interlayer dielectric layer 120 to expose the dummy gate stack; removing the dummy gate stack to form a cavity; and forming a gate stack in the cavity.

To further fabricate a specific transistor device, as shown in FIG. 5, after forming the interlayer dielectric layer 120, the process may further comprise: forming contact holes 122 in the interlayer dielectric layer 120 to expose a portion of the active area; and forming a contact layer 124 on the exposed active area. Herein, the step of forming the contact layer 124 comprises: forming a metal layer to cover sidewalls of the contact hole 122 and the exposed active area; annealing so that the metal layer material reacts with the exposed active area to form a metal semiconductor material; and removing the unreacted material of the metal layer. By forming the contact layer 124 after formation of the interlayer dielectric layer 120, it is advantageous in that the damage to the formed contact layer 124 during the process for removing at least a portion of the spacer 104 is reduced.

Herein, the material of the metal layer may be one of Ni, Ni-containing metal alloy, Ti, and Co, or any combination thereof. In the event that the semiconductor substrate 100 is a Si substrate, the material of the contact layer 124 may be NiSi₂, TiSi₂, or CoSi₂, etc.

According to an embodiment of the present invention, the method for manufacturing a transistor may further comprise: filling the contact holes 122 with a conductive metal to form contact plugs 140, as shown in FIG. 6. The step of forming the contact plug may comprise: forming a liner of e.g. Ti/TiN or Ta/TaN, to cover sidewalls and bottom of the contact hole 122; and forming on the liner a conductive metal layer, the material of which may be one of Al, W, TiAl, and Cu, or any combination thereof.

In accordance with the method for manufacturing a transistor of the present invention, after the spacer is formed to surround the gate stack or dummy gate stack, at least a portion of the spacer is removed to expose a portion of the active area, and then the gate stack or dummy gate stack, the spacer and the exposed active area are covered by the interlayer dielectric layer with a dielectric constant smaller than that of the material of the removed spacer. Namely, the original spacer material is replaced by the interlayer dielectric layer with a smaller dielectric constant, which forms the isolation between the gate region and the source/drain region as well as between the gate region and the contact plug. In fact, this reduces the dielectric constant between the gate region and the source/drain region as well as between the gate region and the contact plug, and thus makes it possible to reduce the capacitance between the gate region and the source/drain region as well as between the gate region and the contact plug, and helps to improve the performance of the transistor.

It should be noted that the present invention is disclosed in the above description by taking the fabrication of a MOSFET transistor as an example, the skilled in the art will appreciate that, according to the spirit and principle of the present invention, the manufacturing method of the present invention is not limited to MOSFET, but can also be applied to other types of transistors like a bipolar transistor, a junction field effect transistor, as well as to other semiconductor devices. Therefore, the protection scope of the present invention also covers a method for manufacturing a semiconductor device, which comprises the steps of the method for manufacturing a transistor mentioned above.

Although the present invention has been described with reference to the embodiments which have been contemplated currently, it should be appreciated that the present invention is not limited to the disclosed embodiments. On the contrary, the present invention intends to cover all modifications and equivalents which fall within the spirit and scope of the appended claims. The scope of the appended claims should be interpreted to the broadest extent to cover all these modifications and equivalents.

What is claimed is:

1. A method for manufacturing a transistor, comprising:
defining an active area on a semiconductor substrate, and forming on said active area a gate stack or a dummy gate stack, a source/drain extension region, a spacer and a source/drain region, wherein said source/drain extension region is embedded in said active area and self-aligned on both sides of said gate stack or dummy gate stack, said spacer surrounds said gate stack or dummy gate stack, and said source/drain region is embedded in said active area and self-aligned outside said spacer;
removing at least a portion of said spacer to expose a portion of said active area; and
forming an interlayer dielectric layer to cover said gate stack or dummy gate stack, said spacer and said exposed active area, wherein the dielectric constant of the material of said interlayer dielectric layer is smaller than that of the material of said removed spacer.

2. The method according to claim 1, wherein after forming the interlayer dielectric layer, the method further comprises:
forming contact holes in said interlayer dielectric layer to expose a portion of said active area; and
forming a contact layer on said exposed active area.

3. The method according to claim 2, wherein the step of forming a contact layer comprises:
forming a metal layer to cover sidewalls of said contact hole and said exposed active area;
annealing so that the material of said metal layer reacts with said exposed active area to form a metal semiconductor material; and
removing the unreacted material of said metal layer.

4. The method according to claim 1, wherein said spacer comprises a spacer base layer and a primary spacer formed on said spacer base layer, and when the dielectric constant of the material of said primary spacer is larger than that of the material of said spacer base layer, the step of removing at least a portion of said spacer comprises: removing said primary spacer.

5. The method according to claim 4, wherein when the material of said semiconductor substrate is Si, the material of said spacer base layer is silicon oxide, and the material of said primary spacer is silicon nitride, the dielectric constant of the material of said interlayer dielectric layer is smaller than that of silicon nitride.

6. The method according to claim 5, wherein the dielectric constant of the material of said interlayer dielectric layer is smaller than that of silicon oxide.

7. The method according to claim 5, wherein when the material of said semiconductor substrate is Si, the material of said interlayer dielectric layer is C-doped silica glass.

8. The method according to claim 1, wherein after forming the interlayer dielectric layer, the method further comprises:
planarizing said interlayer dielectric layer to expose said dummy gate stack;
removing said dummy gate stack to form a cavity; and
forming the gate stack in said cavity.

9. A method for manufacturing a semiconductor device, which comprises at least one transistor, comprising at least:
defining an active area on a semiconductor substrate, and forming on said active area a gate stack or a dummy gate stack, a source/drain extension region, a spacer and a source/drain region, wherein said source/drain extension region is embedded in said active area and self-aligned on both sides of said gate stack or dummy gate stack, said spacer surrounds said gate stack or dummy gate stack, and said source/drain region is embedded in said active area and self-aligned outside said spacer;
removing at least a portion of said spacer to expose a portion of said active area; and
forming an interlayer dielectric layer to cover said gate stack or dummy gate stack, said spacer and said exposed active area, wherein the dielectric constant of the material of said interlayer dielectric layer is smaller than that of the material of said removed spacer.

10. The method according to claim 9, wherein after forming the interlayer dielectric layer, the method further comprises:
forming contact holes in said interlayer dielectric layer to expose a portion of said active area; and
forming a contact layer on said exposed active area.

11. The method according to claim 10, wherein the step of forming a contact layer comprises:
forming a metal layer to cover sidewalls of said contact hole and said exposed active area;
annealing so that the material of said metal layer reacts with said exposed active area to form a metal semiconductor material; and
removing the unreacted material of said metal layer.

12. The method according to claim 9, wherein said spacer comprises a spacer base layer and a primary spacer formed on said spacer base layer, and when the dielectric constant of the material of said primary spacer is larger than that of the material of said spacer base layer, the step of removing at least a portion of said spacer comprises: removing said primary spacer.

13. The method according to claim 12, wherein when the material of said semiconductor substrate is Si, the material of said spacer base layer is silicon oxide, and the material of said primary spacer is silicon nitride, the dielectric constant of the material of said interlayer dielectric layer is smaller than that of silicon nitride.

14. The method according to claim 13, wherein the dielectric constant of the material of said interlayer dielectric layer is smaller than that of silicon oxide.

15. The method according to claim 13, wherein when the material of said semiconductor substrate is Si, the material of said interlayer dielectric layer is C-doped silica glass.

16. The method according to claim 9, wherein after forming the interlayer dielectric layer, the method further comprises:
planarizing said interlayer dielectric layer to expose said dummy gate stack;
removing said dummy gate stack to form a cavity; and
forming the gate stack in said cavity.
